(19) United States
(12) Patent Application Publication
(10) Pub. No.: US 2005/0066897 A1
(43) Pub. Date: Mar. 31, 2005

(54) System, method and aperture for oblique deposition

(75) Inventors: Kalman Pelhos, Pittsburgh, PA (US); Timothy J. Klemmer, Pittsburgh, PA (US); Michael A. Seigler, Pittsburgh, PA (US)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Seagate Technology LLC, Scotts Valley, CA (US)

(21) Appl. No.: 10/673,795

(22) Filed: Sep. 29, 2003

(51) Int. Cl. C23C 16/00

(52) U.S. Cl. 118/721; 427/248.1

(57) ABSTRACT

A deposition system including a shadow mask with one or more apertures, and a method are described for oblique deposition of tilted thin films with azimuthal symmetry. The deposition system is used with physical vapor deposition processes to provide improved control of the angle of incidents of the flux combined with rotation of the substrate to create titled thin films with improved properties compared to conventional oblique deposition techniques.

### CROSS-REFERENCE TO RELATED APPLICATION(S)

The present application is related to the concurrently filed applications Ser. No. ______, “Magnetic Storage Media Having Tilted Magnetic Anisotropy;” and Ser. No. ______, “System, Method and Collimator for Oblique Deposition.”

### BACKGROUND OF THE INVENTION

1. Field of the Invention

The present invention relates generally to the field of oblique deposition by physical vapor deposition processes. In particular, the present invention relates to an improved method for oblique deposition of tilted thin films with azimuthal symmetry on circular substrates.

2. Description of the Relevant Art

Physical Vapor Deposition (PVD) processes are widely used in forming many different thin films including magnetic films for magnetic recording media. The properties of the thin films may be manipulated, not only by the material used, but also by the method of deposition and apparatus used. In addition the film properties are affected by the film thickness and uniformity, wherein the quality of the film is affected by control of those properties during deposition.

Physical vapor deposition (PVD) processes are atomistic deposition processes wherein material is vaporized from a source in the form of atoms, molecules, or clusters of atoms or molecules. Then the vaporized species travel through a vacuum, low pressure or plasma environment to the substrate where they condense. The vaporized species generally travel in a straight-line path (unless they collide with residual gas molecules/atoms) and will tend to deposit on any surface that they contact. It is important to note that vaporized species leave the source in a flux with an angular distribution of finite (non-zero) width, i.e. there is a unique direction that most particles will travel, but there is a certain amount of dispersion from this average direction (a distribution of particles flying at slightly different angles).

Oblique deposition is a modification of the deposition process that is used to manipulate crystallographic, magnetic or other properties of thin films. Oblique deposition is the modification of deposition geometry so that the species being deposited on average strike at an angle more than 0° measured with respect to the surface normal of the substrate resulting in a tilted thin film. Suitable systems for oblique deposition generally include physical vapor deposition (PVD) processes such as: ion beam deposition (IBD), sputtering, molecular beam epitaxy, laser ablation and vacuum evaporation. Oblique deposition generally requires directional control of the deposition process and mainly has been applied to stationary or non-rotating substrates.

However, the adaptation of PVD processes, for oblique deposition has not been successful in producing thin films with the desired properties or uniformity in the deposited material. Previous attempts to achieve tilted thin films primarily utilized one of two different techniques to attempt directional control for oblique deposition. One technique was to utilize a point-like source, for example a conventional sputter gun or IBD, to control the flux angle relative to a stationary substrate. A second technique uses a box with tilted slats placed over the immobile substrate to attempt control of the flux angle. These techniques result in poor quality thin films with an undesirably wide distribution of textures and uneven thickness. Additionally, deposition with a single point source is very slow compared to the flux volume from conventional non-oblique PVD processes, hampering use in large-scale production. The resulting thin films also have unidirectional pattern that is not desirable for applications with circular or radial patterns. Consequently, there remains a need in the art for a method of oblique deposition with sufficient throughput while maintaining incident angle control of the flux such that oblique deposited thin films with substantially uniform thickness and texture are achieved. In addition, the development of an improved method for deposition of tilted thin films with alternative configurations and azimuthal symmetry is also desired.

### BRIEF SUMMARY OF THE INVENTION

The deposition system of the present invention includes a shadow mask to control the angle of incidence of the vaporized species thereby resulting in a tilted thin film with improved uniformity in thickness and texture over other oblique deposition processes. The deposition system allows higher throughput while creating tilted thin films with circumferential and radial patterns and/or azimuthal symmetry. The deposition system controls the relationship of the incident beam of vaporized species to the underlying substrate to further define or collimate the deposition beam and thereby improve the properties of the resulting tilted thin film. Additionally, the deposition system can be used in physical vapor deposition processes where the substrate is rotated thereby advantageously improving the continuity and uniformity of the deposited thin film.

The deposition system is customized to control the angular deviation allowed from perfect circumferential or radial alignment in the resulting tilted thin film. The width of the aperture may be constant or change as the function of the distance from the center of the substrate. In addition, the shape of the aperture may also compensate for the non-uniformity of thickness related to the distance of the substrate from the source of vaporized species.

The thickness of the shadow mask may be varied to further improve collimation of the deposition beam at the substrate. Additionally, the shadow mask may be combined with an additional collimator to further enhance the collimation of the deposition beam at the surface in all directions.

The deposition system may alternatively include several apertures in a single shadow mask to improve throughput. Each aperture may have its own oblique deposition source and be separated from the remaining apertures by walls.

### BRIEF DESCRIPTION OF THE DRAWINGS

FIG. 1 is a perspective representation of oblique deposition geometry relative to a substrate.

FIG. 2 is a cross-sectional view of a deposition system consistent with the present invention.

FIG. 3 is a top view of a shadow mask consistent with the present invention.

FIG. 4 is a perspective view of a shadow mask oriented for deposition of a thin film with a radial pattern overlying a circular substrate.

FIG. 5 is a perspective view of the inventive shadow mask with aperture oriented relative to the deposition beam for deposition of a thin film with a circumferential pattern overlying a circular substrate.

FIG. 6 is a top view of an exemplary shadow mask with multiple apertures for creating a radial pattern.

FIG. 7 is a top view of an inventive shadow mask with a second exemplary arrangement of multiple apertures for creating a circumferential pattern.

FIG. 8 is a top view of a unidirectional pattern related to a circular substrate.

FIG. 9 is a top view of a circumferential pattern related to a circular substrate.

FIG. 10 is a top view of radial pattern of a circular substrate.

### DETAILED DESCRIPTION

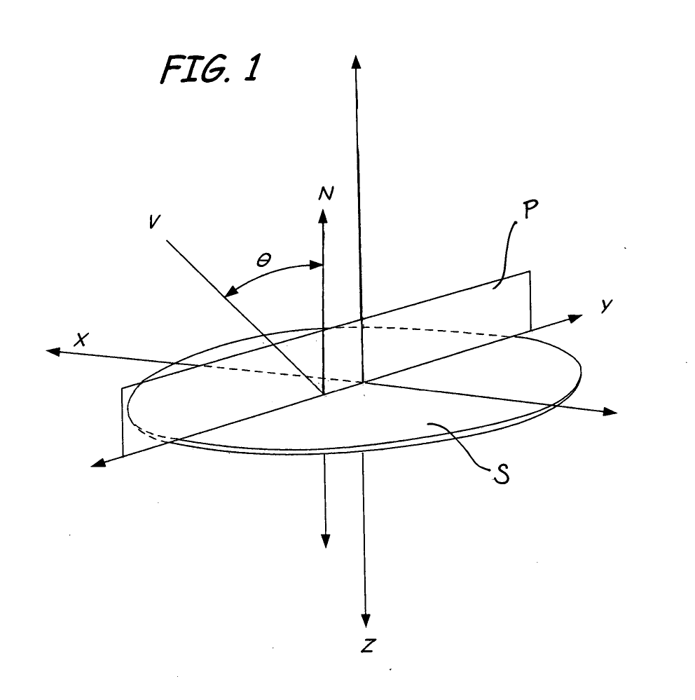

FIG. 1 shows an oblique deposition beam as a vector V striking a substrate S where the position of the vector is relative to the X, Y, and Z reference axes. Oblique deposition is generally defined as deposition geometry where a beam of atoms or particles impinges upon the surface of a wafer at a well-defined angle, θ, as measured with respect to a surface normal, N. The angle, θ, may also be referred to as the angle of incidence. Additionally, the plane of incidence P is shown. The Z axis corresponds to a central surface normal.

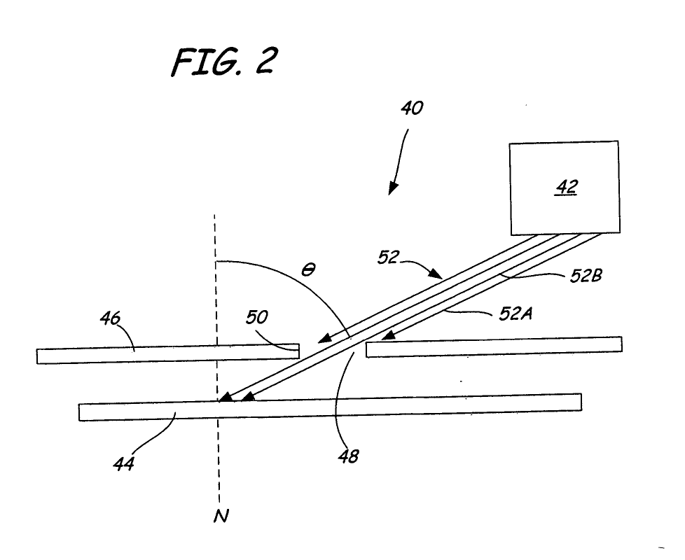

The present invention is a deposition system incorporating a novel shadow mask with at least one aperture, and a method of use thereof for incident angle control of oblique deposited vaporized species. An example deposition system, consistent with the present invention is shown in FIG. 2. The deposition system 40 of the present invention includes a source 42, a substrate 44, and a shadow mask 46 including at least one aperture 48 with side walls 50. The deposition system is prepared by placing the shadow mask 46 between the source 42 and the substrate 44. The deposition system 40 operates by applying energy, consistent with known methods of oblique deposition by (PVD) to the source 42 causing the release of species, such as atoms, molecules, or clusters.

The vaporized species 52 travel along a distribution of trajectories collectively referred to as a deposition beam directed at approximately oblique angle θ towards aperture 48 and substrate 44. Oblique angle θ is measured with respect to a surface normal of the substrate 44. Vaporized species 52A that are not aligned with aperture 48, strike shadow mask 46 and consequently do not reach substrate 44. The vaporized species 52B desirably travel at an angle so as to be aligned with aperture 48 thereby traveling through aperture 48 of shadow mask 46 to strike substrate 44. Preferably, the deposition beam is properly oriented such that a majority of the vaporized species pass through aperture 48 at approximately oblique angle θ. Oblique angle θ is at least approximately 35° to at most approximately 90°. Preferably oblique angle θ is between approximately 55° to approximately 75°. An example preferred angle is approximately 65°.

The substrate 44 is generally circular and may be formed from a variety of materials. Special preparation of the substrate 44 is typically not required. Examples of suitable materials include silicon wafers, glass discs and aluminum substrates. Substrate 44 rotates above aperture 48 of shadow mask 46 as shown in FIG. 2. The substrate may complete one 360° revolution during deposition or alternatively may rotate several complete revolutions relative to aperture 48. The method of the present invention will assist formation of a tilted thin film over the entire surface of substrate 44.

Source 42 preferably generates vaporized species traveling at a distribution of angles surrounding an oblique angle θ measured relative to the surface normal of the substrate. Throughput of the system improves with narrower distributions of vaporized species from source 42. Source 42 is a type commonly used for physical vapor deposition processes including, but not limited to: ion beam deposition (IBD), sputtering, evaporation, molecular beam epitaxy (MBE), and pulsed laser deposition. Source 42 may be modified to direct the vaporized species at approximately oblique angle θ toward aperture 48 and substrate 44.

The deposition system as shown in FIG. 2 is oriented such that the vaporized species travel upward to reach substrate 44 in opposition to the direction of gravity. The deposition system may be operated in any system orientation, including up-side-down as shown in FIG. 2, aligned with the direction of gravity or right-side-up, sideways or in a zero gravity environment. In all cases, the surface of substrate 44 upon which the tilted thin film is deposited faces towards the shadow mask 46 and source 42.

The deposition system 40 limits the vaporized species striking substrate 44 to a portion of the deposition beam in which the vaporized species are traveling within a limited range of angles surrounding the selected angle of incidence, θ. Deviations in the orientations, pattern, and symmetry in the resulting tilted thin film from perfect circumferential or radial alignment, and azimuthal symmetry are influenced by the allowed angular deviation in the oblique deposition beam.

The shadow mask 46 is a block or sheet that defines at least one aperture 48 with side walls 50. Shadow mask 46 will typically be made from metal materials, but may alternatively be formed from any material that is compatible with the deposition environment. The shadow mask 46 has a thickness within a range approximately from less than a millimeter to about a centimeter. Where the shadow mask 46 is very thin, it may also comprise a framework-type support, such as a wire grid.

The shadow mask 46 may vary in thickness to improve uniformity of the deposition beam related to the quantity of vaporized species passing through aperture 48. Thickness of shadow mask 46 may vary, for example an increase in thickness from center to outer edge, to adjust for variation in output from source 42. How the thickness is varied depends on the specifications of source 42.

The thickness of the shadow mask may also vary in order to control the overall collimation of the deposition beam at the surface of the substrate. “Well-collimated” deposition refers to limiting or narrowing the angular distribution to a defined range of angles around the desired deposition angle, or angle of incidence, θ. A thicker mask will improve the collimation of the deposition beam at the substrate surface in a direction perpendicular to the aperture 48. Additionally, the allowed angular deviation from the desired angle of incidence, θ, is limited by the size and shape of aperture 48; including thickness of shadow mask 46. A combination of variation in the thickness of shadow mask 46 along with variation in the size and shape of aperture 48 may be used to improve uniformity in both collimation and quantity of vaporized species deposited across substrate 44.

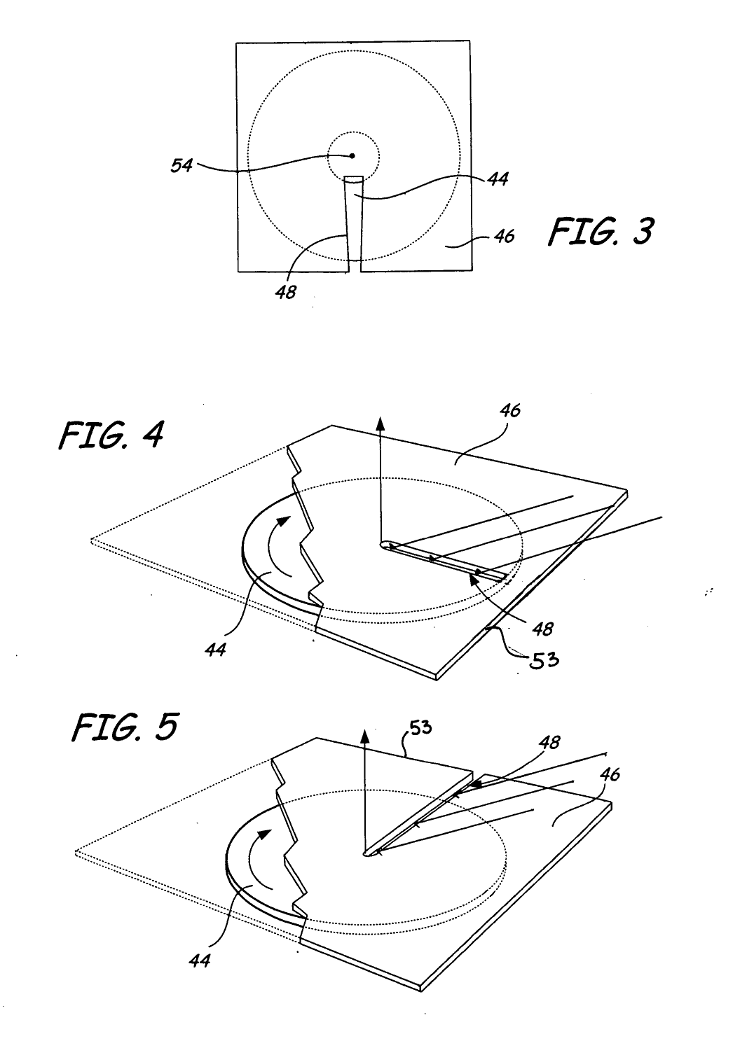

FIG. 3 shows an embodiment of shadow mask 46 with aperture 48 relative to substrate 44. The width of the aperture, as shown, varies a function of distance from the center 54. As the width of the aperture 48 narrows, the allowed angular deviation in the directionality of the angle of incidence of the vaporized species also decreases. By varying the shape of the aperture one can control the angular distribution of alignment in the thin film as a function of distance from the center 54 of the shadow mask 46, if desired. Alternatively, aperture 48 may have a constant width.

The width of the aperture may also be altered to compensate for the non-uniformity of thickness seen in prior forms of oblique deposition. The non-uniformity in thickness may result from a greater flux density of vaporized species to areas of the substrate that are closer to the source of deposition. The quantity of vaporized species (also referred to as flux) is reduced whenever the area of aperture 48 is reduced. By narrowing the aperture where the flux density from the source (not shown) is higher and/or widening the aperture 48 where the relative flux density is lower, the resulting uniformity in thickness of the thin film can be improved.

As shown in FIG. 3, the shadow mask 46 generally extends beyond the area of substrate 44. The aperture may extend to the edge 53 of shadow mask 46 as shown in FIG. 3 or alternatively may be closed forming a defined opening in shadow mask 46 as sown in FIG. 4. In general, the length of aperture 48 is related to the radius of substrate 44. The aperture may alternatively be defined so as to direct deposition to less than the entire surface of substrate 44.

FIGS. 4 and 5 provide alternative perspective views of deposition system 40. In FIGS. 4 and 5, an oblique deposition beam of vaporized species 52 strikes substrate 44 through shadow mask 46. The shadow mask 46 of deposition system 40 has a least one long narrow aperture 48 that is oriented either perpendicular as seen in FIG. 4 or parallel as seen in FIG. 5 to an deposition beam of vaporized species 52 from a source 42 (not shown). Oblique deposition occurring through the shadow mask 46 results in only a radial segment of the substrate 44 being deposited at any given instant allowing the segment to have a well-defined pattern either parallel or perpendicular to the deposition beam.

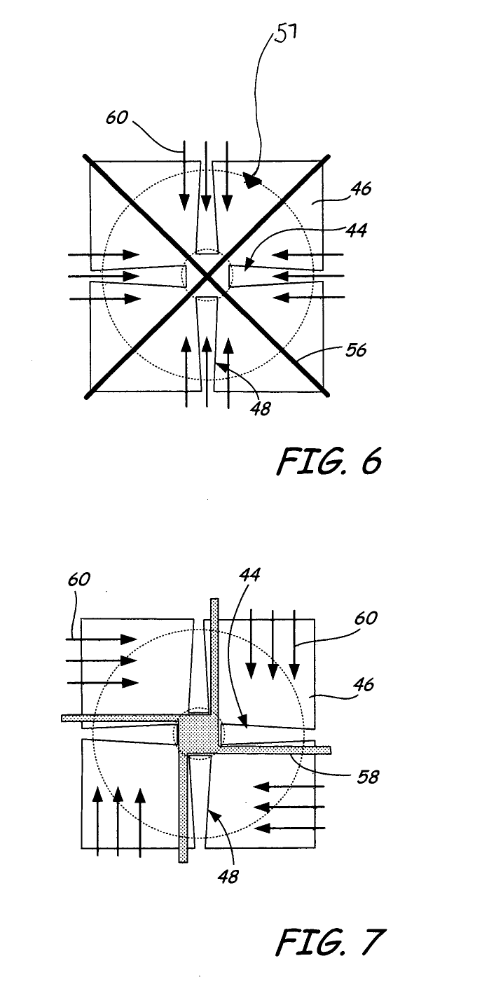

Additional embodiments of deposition system 40 are shown in FIGS. 6 and 7. Shadow mask 46 may include a plurality of apertures 48 in order to improve throughput of the deposition system 40. Examples of shadow masks with multiple apertures and suitable wall construction are shown in FIGS. 6 and 7. In FIG. 6, each aperture 48 has its own source 42, (not shown) represented by deposition beam 60, and separated by a sectioning wall 56 attached perpendicular to the shadow mask 46. Sectioning wall 56 has thickness such that each deposition beam 60 provides vaporized species for only one aperture 48. The thickness of sectioning wall 56 may extend from the shadow mask to the height of deposition chamber enclosing the deposition system. However, any thickness of sectioning wall 56 which sufficiently prevents leakage of vaporized species from one zone 57 to another is sufficient. FIG. 6 shows an example with four zones, but the number of zones is essentially only limited by deposition system size limitations. FIG. 6 is suitable for the deposition of tilted thin films with a radial pattern and azimuthal symmetry.

Shadow mask 46 as shown in FIG. 7 also has four zones and is likewise only limited by deposition system size limitations. In FIG. 7 the shadow mask 46 has four apertures 48 arrayed over substrate 44. The sectioning wall 58 attached to the shadow mask 46 has a pinwheel type structure suitable for the illustrated directionality of the deposition beam 60. The tilted thin film resulting from the combination of sectioning wall 58 and shadow mask has a circumferential pattern and azimuthal symmetry.

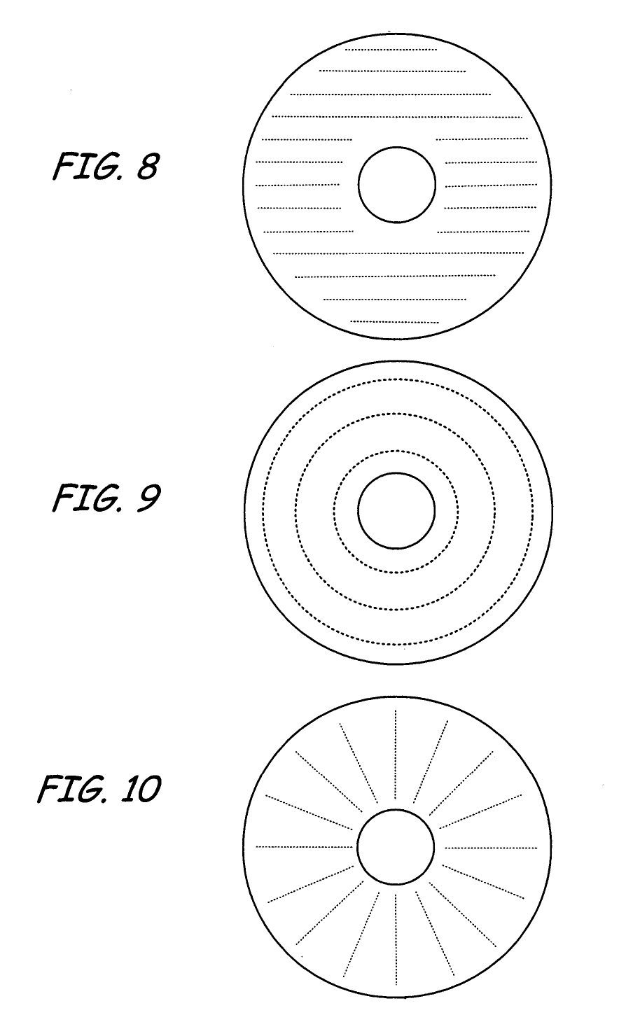

The deposition system 40 of the present invention is useful for oblique deposition of thin films with several different pattern types. While conventional oblique deposition methods primarily produced films with a unidirectional pattern, the deposition system 40 and shadow mask 46 may be used to produce pattern types, such as circumferential and radial patterns. These pattern types are further illustrated below and in FIGS. 8, 9, and 10.

A unidirectional pattern is defined as when all the grains (or other feature of interest) are oriented generally parallel throughout the substrate, for example, as shown in FIG. 8. A unidirectional pattern is unsuitable for applications, such as hard discs, that are circular for purposes of rotation during use and consequently perform optimally where pattern is of a circular nature. The deposition system 40 of the present invention overcomes previous problems limiting the oblique deposition of tilted thin films suited for circular substrates.

The inventive deposition system is preferably utilized to deposit tilted thin films with either circumferential or radial patterns on rotating circular substrates. A circumferential pattern is defined as the organization of the grain orientations, or other feature of interest including but not limited to: C-axis, crystallographic axis, easy axis, and magnetocrystalline anisotropy; around a central point or axis. A circumferential pattern on a circular substrate is represented in FIG. 9. A radial pattern is defined is defined as the organization of orientations of the grains, or other feature of interest including but not limited to C-axis, crystallographic axis, easy axis, and magnetocrystalline anisotropy; along radial axes from a central point. A radial pattern on a circular substrate is represented in FIG. 10.

It is especially desirable for certain applications using circular substrates to possess azimuthal symmetry. Azimuthal symmetry is defined by identity between cross-sections of the thin film taken through the center. For example, a tilted thin film deposited on a circular wafer will possess azimuthal symmetry when a cross section along a radius to the central axis are the same in appearance, in other words are symmetrical. Azimuthal symmetry combined with a circumferential or radial pattern in the magnetic anisotropy of a tilted thin film is desired for applications such as magnetic storage media (e.g. hard discs). Magnetic storage media is preferably consistent in character such that it does not vary other than for the stored signals as the media rotates relative to a transducing head.

The phrase “tilted thin film” of the present invention refers to thin films produced by oblique deposition. The “tilt” produced by oblique deposition refers generally to the readily observable (by electron microscopy) tilt in the grains or other crystal related structures within a cross-section of an oblique deposited material. Use of the inventive deposition system 20 is not limited to deposition of particular types of thin films, other that the desire for the particular thin film to be oblique deposited. For example, the inventive deposition system may be used to deposit seedlayer structures and magnetic material layers.

The thin films produced with the inventive deposition system 40; depending on the material and specifics of the physical vapor deposition process used; result in tilted grain growth, tilted crystallographic texture, anisotropic stress, correlated surface roughness, or any combination thereof. For example, in magnetic materials, the symmetry, pattern or orientation of the deposited layer may be focused on the magnetic anisotropy, especially the magnetocrystalline anisotropy, of the tilted thin film. The magnetic anisotropy, which generally related to the crystallographic characteristics of the material, may be separately analyzed. The magnetic anisotropy is of special interest in hard drive technologies where there is much interest in creating thin films with tilted magnetic anisotropy also referred to as tilted media.

It is advantageous to combine the teachings of the present invention with the teachings of U.S. patent application Ser. No. ______ titled “Magnetic Storage Media Having Tilted Magnetic Anisotropy,” filed concurrently with the present application and incorporated herein by reference, hereinafter referred to as the “Tilted Media Application”. The combination of the Tilted Media Application with the teachings of the present invention is useful to produce magnetic media with tilted C-axis and tilted magnetic anisotropy, wherein the tilted C-axis and tilted magnetic anisotropy are arranged in a circumferential or a radial pattern and additionally possess azimuthal symmetry.

The shadow mask 46 of the present invention may alternatively be combined with a separate collimator, for example a honeycomb style grid or the subject of the related application Ser. No. ______, “System, Method and Collimator for Oblique Deposition,” filed concurrently with the present application and incorporated herein by reference. The combination of the inventive shadow mask 46 with either a built-in or separate collimator can be used to further enhance the collimation of the deposition beam at the surface of the substrate in one a plurality of directions or all directions concurrently.

Although the present invention has been described with reference to examples and preferred embodiments, workers skilled in the art will recognize that changes may be made in form and detail without departing from the spirit and scope of the invention.

1. A deposition system for oblique deposition comprising:
a source of vaporized species traveling at a first distribution of angles surrounding an oblique angle θ measured relative to a surface normal of a substrate;
a shadow mask including at least one aperture located between the source and a substrate wherein the shadow mask intercepts a portion of the vaporized species traveling at the first distribution thereby limiting the vaporized species passing through the aperture to traveling at a second distribution of angles surrounding an oblique angle θ; and
the substrate contacted by the second distribution of vaporized species, the species forming a tilted thin film on the substrate.

2. The deposition system of claim 1 wherein the source of vaporized species is a physical vapor deposition source.

3. The deposition system of claim 1 wherein the oblique angle θ is greater than 35° and less than 90°.

4. The deposition system of claim 1 wherein the oblique angle θ is greater than 55° and less than 75°.

5. The deposition system of claim 1 wherein the shadow mask limits the vaporized species traveling through the aperture so as to organize the angles of the vaporized species thereby forming a tilted thin film having azimuthal symmetry.

6. The deposition system of claim 1 wherein the shadow mask limits the vaporized species traveling through the aperture so as to organize the angles of the vaporized species into a circumferential pattern.

7. The deposition system of claim 1 wherein the shadow mask limits the vaporized species traveling through the aperture so as to organize the angles of the vaporized species into a radial pattern.

8. The deposition system of claim 1 wherein the aperture has width and the width is non-constant from a first end to a second end.

9. The method of claim 1 wherein the substrate is a circular disc for a recording media.

10. The deposition system of claim 1 wherein the shadow mask has at least two apertures.

11. A method for oblique deposition onto a substrate, the method comprising:
directing vaporized species toward a substrate at a distribution of angles of incidence about angle θ measured relative to a surface normal of the substrate; and
narrowing the angular distribution.

12. The method of claim 11 wherein the distribution of angles of incidence is narrowed by permitting only a portion of the vaporized species traveling at approximately angle θ to pass through an aperture in a shadow mask and deposit on the substrate.

13. The method of claim 11 wherein the distribution of the angles of incidence is narrowed by intercepting a portion of the vaporized species not traveling at about angle θ, wherein the species are intercepted with a shadow mask.

14. The method of claim 11 comprising the additional step of rotating the substrate while depositing the vaporized species on the substrate.

15. The method of claim 14 comprising the additional step of forming a single continuous film of the vaporized species wherein the angles of incidence of the vaporized species are organized into azimuthal symmetry.

16. The method of claim 14 comprising the additional step of forming a single continuous film of the vaporized species wherein the angles of incidence of the vaporized species are organized into a circumferential pattern.

17. The method of claim 14 comprising the additional step of forming a single continuous film of the vaporized species wherein the angles of incidence of the vaporized species are organized into a radial pattern.

18. A shadow mask for oblique deposition by physical vapor deposition onto a substrate, the shadow mask comprising a slot aperture, the slot aperture having generally radial direction relative to a circular substrate.

19. The device of claim 18 wherein the aperture has width and the width is non-constant from a first end to a second end.

20. The shadow mask of claim 18 comprising a plurality of slot apertures separated by walls adjacent to the shadow mask.
